(19) United States
(12) Patent Application Publication
(10) Pub. No.: US 2015/0185623 A1
(43) Pub. Date: Jul. 2, 2015

(54) OPTICAL DEVICE, LITHOGRAPHY APPARATUS AND MANUFACTURING METHOD OF ARTICLE

(71) Applicant: CANON KABUSHIKI KAISHA, Tokyo (JP)

(72) Inventors: Wataru Yamaguchi, Utsunomiya-shi (JP); Hideki Ina, Tokyo (JP)

(21) Appl. No.: 14/580,028

(22) Filed: Dec. 22, 2014

(30) Foreign Application Priority Data
Dec. 27, 2013 (JP) 2013-272042

(51) Int. Cl. G03F 7/20

(52) U.S. Cl. CPC G03F 7/70141

(57) ABSTRACT

An optical device provided with an optical system illuminating light on a target surface, including: three light sources configured to emit light beams of different wavelengths; a first fiber configured to guide, to the optical system, two light beams among the three light beams from the three light sources; and a second fiber configured to guide, to the optical system, the light beam of a wavelength other than the two light beams. A cutoff wavelength of the first fiber differs from a cutoff wavelength of the second fiber.

### BACKGROUND OF THE INVENTION

1. Field of the Invention

The present invention relates to an optical device, a lithography apparatus and a manufacturing method of an article.

2. Description of the Related Art

Japanese Patent Laid-Open No. 2008-139820 relates to a microscope in which three light beams emitted from three light sources emitting light beams of different wavelengths or four light beams emitted from four light sources emitting light beams of different wavelengths are composed via collimator lenses and are made to enter a single fiber. In the described microscope, collimator lenses of different optical properties are used for each of the light beams emitted from each of the light sources so that an incidence angle of the composite light beam entering this fiber becomes smaller than a critical angle of the fiber and an image from the light source becomes the largest in a range not exceeding an input end face of the fiber.

In a case in which all the light beams emitted from a plurality of light sources of different wavelengths are guided by using a single fiber as described in Japanese Patent Laid-Open No. 2008-139820, there is a possibility that, when vibration and bending stress are applied to the fiber from outside, a degree of light quantity loss of light beam from each light source may be varied due to a difference in stress resistance for each wavelength.

Therefore, in a case in which a wavelength with high reflection characteristics varies depending on a difference in an object to be illuminated with the light or a difference in illumination position on the object, there is a possibility that a contrast in an image to be obtained may be lowered or measurement accuracy in the position obtained from the image may be lowered.

### SUMMARY OF THE INVENTION

The present invention provides an optical device capable of reducing variation in light quantity loss as compared with a case in which all light beams of different wavelengths emitted from a plurality of light sources are guided by using a single fiber.

An optical device of the present invention is an optical device provided with an optical system illuminating light on a target surface, the optical device including: three light sources configured to emit light beams of different wavelengths; a first fiber configured to guide, to the optical system, two light beams among the three light beams from the three light sources; and a second fiber configured to guide, to the optical system, the light beam of a wavelength other than the two light beams, wherein a cutoff wavelength of the first fiber differs from a cutoff wavelength of the second fiber.

Further features of the present invention will become apparent from the following description of exemplary embodiments with reference to the attached drawings.

### BRIEF DESCRIPTION OF THE DRAWINGS

FIG. 1 is a configuration diagram of an optical device according to a first embodiment.

FIGS. 2A and 2B are configuration diagrams of optical devices according to a second embodiment.

FIG. 3 is a configuration diagram of an optical device according to a third embodiment.

FIG. 4 is a configuration diagram of an optical pickup according to a fourth embodiment.

FIG. 5 is a configuration diagram of a position detector device according to a fifth embodiment.

FIG. 6A is a configuration diagram of a lithography apparatus according to a sixth embodiment and FIG. 6B is a configuration diagram of a position detector device according to the sixth embodiment.

### DESCRIPTION OF THE EMBODIMENTS

Each of the following embodiments relates to an optical device which is provided with three or more light sources emitting light beams of different wavelengths, and which guides three or more light beams emitted from the light sources and irradiates (i.e., illuminates) a target surface with the light beams while reducing variation in light quantity loss from each of the light sources as much as possible.

### First Embodiment

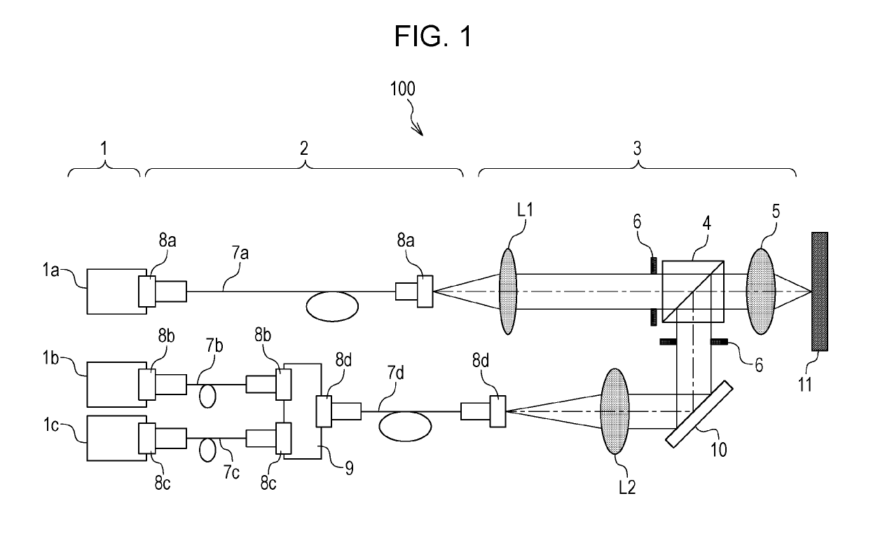

FIG. 1 is a diagram illustrating a configuration of an optical device 100 according to a first embodiment. The optical device 100 is a microscope for which there is a demand that linearly polarized light polarized in a predetermined direction is to be illuminated.

The optical device 100 is provided with a light source 1 (1a, 1b and 1c), a light guide unit 2 and an illumination optical system 3. The illumination optical system 3 is an optical system which illuminates light toward a target surface. Light beams emitted from the light source 1 are guided to the illumination optical system (i.e., an optical system) 3 via the light guide unit 2 and composed with light beams incident from different optical paths at a dichroic prism 4 in the illumination optical system 3, and the composed light beam is made to illuminate a target surface 11 via an objective lens 5 in the same illumination optical system 3.

The three light sources 1a, 1b and 1c are laser light sources emitting light beams of different wavelengths. The wavelength of light beam emitted from the light source 1a is defined as λ1, the wavelength of light beam emitted from the light source 1b is defined as λ2 and the wavelength of light beam emitted from the light source 1c is defined as λ3 (λl<λ2<λ3). Here, a wavelength difference between λ2 and λ3 is set smaller than a wavelength difference between λ1 and λ2 (that is, λ2 and λ3 are close to each other among the wavelength of light beams emitted from light source 1a, 1b, and 1c).

As a laser light source of the light source 1, semiconductor laser, gas laser which uses Ar or He—Ne as a medium, and the like are used. Light sources of different kinds may be used in combination as the light sources 1a, 1b and 1c.

The light guide unit 2 is provided with a fiber 7a (i.e., a second fiber) which guides the light beam emitted from the light source 1a to the illumination optical system 3, and connectors 8a provided at both ends of the fiber 7a, a fiber 7b which guides the light beam emitted from the light source 1b, and connectors 8b provided at both ends of the fiber 7b, a fiber 7c which guides the light beam emitted from the light source 1c, and connectors 8c provided at both ends of the fiber 7c, and a coupler 9 which composes light beams guided by the fiber 7b and the fiber 7c. The light guide unit 2 is further provided with a fiber 7d (i.e., a first fiber) which guides the light beam emitted from the coupler 9 to the illumination optical system 3, and connectors 8d provided at both ends of the fiber 7d.

Among the fibers 7a to 7d, the light beam emitted from the light source 1a is eventually guided by the fiber 7a to the illumination optical system 3, and the light beams from the light sources 1b and 1c are eventually guided by the fiber 7d to the illumination optical system 3. The fibers 7a and 7d are fibers of different cutoff wavelengths. The cutoff wavelength refers to as a boundary wavelength indicating either of a multi-mode dispersion mode or a single-mode dispersion mode is used in propagation of the light beam in a single-mode fiber. Since variation is caused in a manufacturing process, the cutoff wavelength is represented by a wavelength band of a predetermined range.

Typically, in a case in which bending stress is applied to a fiber, a quantity of light guided by the fiber is reduced. This is because, when the bending stress is applied, an angle of the light entering a boundary surface between a core and a clad of the fiber becomes smaller than a critical angle and total reflection of the light is not performed, whereby a part of the light is emitted outside. Since bending stress resistance differs in each wavelength, a degree of light quantity loss becomes more greatly varied among wavelengths as light beams of greater bandwidth differences in wavelength enter the same fiber.

Therefore, in order to reduce variation in the degree of light quantity loss, it is desirable that the light beams of a plurality of wavelengths guided by the fiber 7d are relatively close in wavelength, like λ2 and λ3, among all the wavelengths of the light sources as illustrated in FIG. 1. Conversely, it is desirable to avoid that light beams of wavelengths λ1 and λ3 from entering the fiber 7d in combination.

It is desirable that the fibers 7a to 7d are single-mode fibers that may propagate the light emitted from each light source in the single mode. A single-mode fiber may propagate light while keeping a polarization plane of linearly polarized light, such as light emitted from a laser light source, as much as possible.

In order to guide the light in the single mode while reducing the light quantity loss as much as possible, the fiber 7a having a cutoff wavelength that may transmit a light beam of the wavelength λ1 in the single mode is to be selected, and the fiber 7d having a cutoff wavelength that may transmit light beams of the wavelengths λ2 and λ3 in the single mode is to be selected. For that purpose, a fiber having a wavelength band, as a cutoff wavelength, of a length shorter than the shortest wavelength of the light guided by that fiber is to be selected. Then, when the fiber 7d is to be selected, a fiber of which wavelength band of the cutoff wavelength consists of a wavelength band shorter than the wavelength λ2, and light quantity loss of light of the wavelengths λ2 and λ3 is relatively small is selected.

The illumination optical system 3 is provided with collimator lenses L1 and L2. The collimator lens L1 collimates the light beam emitted from the light source 1a. The collimator lens L2 collimates the light beam emitted light source 1b and the light beam emitted from the light source 1c. The illumination optical system 3 is further provided with a mirror 10 which reflects the light beam having passed through the collimator lens L2 toward a dichroic prism 4, and aperture diaphragms 6 one of which is disposed between the collimator lens L1 and the dichroic prism 4 and the other of which is disposed between the collimator lens L2 and the dichroic prism 4. Further, unillustrated lenses may be disposed in order to keep the shape of the light beams collimated by the collimator lenses L1 and L2.

It is desirable that the collimator lenses L1 and L2 have different in optical properties, such as a focal position and a lens thickness, from each other. For example, it is possible to make diameters of the light beams emitted from the fibers 7a and 7d uniform by selecting the collimator lenses L1 and L2 with appropriate focal positions. Therefore, a difference in image formation magnification of each light caused by a difference in mode field diameters of the fibers 7a and 7d may be corrected.

By not narrowing the number of the optical paths on which the collimator lenses are disposed to one, the curvature of lens, a lens thickness, a glass material and the like may be selected for each of the collimator lenses L1 and L2 to be disposed on each optical path. By suitably selecting these properties, an effect to reduce an influence on chromatic aberration in the target surface 11 may also be produced. In a case in which the collimator lens is constituted by a plurality of collimator lenses as a unit, the correct chromatic aberration may be corrected by adjusting distances between the lenses.

The aperture diaphragms 6 disposed at pupil planes of the illumination optical system 3 may adjust a contrast and a resolution of an image of the target surface 11. In a case in which the difference in wavelengths of the light sources 1a, 1b and 1c is small, numerical apertures may be uniformly adjusted by placing the aperture diaphragm 6 only between the dichroic prism 4 and the objective lens 5 to save the space. Adjustment of the numerical apertures of the aperture diaphragm 6 is performed by adjusting a diaphragm amount of the apertures using an iris diaphragm.

In order to emit a polarized light beam polarized in a predetermined direction, it is desirable that angular deviation in a polarization direction among the polarized light beams after the composition at the dichroic prism 4 is smaller than angular deviation in a polarization direction among the polarized light beams each entering the fibers 7a, 7b, 7c and 7d. In the present embodiment, the polarization direction of light of each wavelength included in the composite light is made to correspond to one another by emitting light toward the dichroic prism 4 in a state in which light emitting ports of the fibers 7a and 7d have been rotated in a predetermine amount.

In a case in which the light is to be guided with the polarization plane of the polarized light being kept more in shape, it is desirable to use a polarization maintaining fiber among single-mode fibers as the fibers 7a, 7b, 7c and 7d. Since non-axisymmetric stress is applied to the core to induce a birefringence in the fiber, it is possible to reduce a change in the polarized light characteristic caused by external vibration and stress.

By configuring the optical device 100 in this manner and adjusting the rotational positions of the light emission ports as described above, the polarization directions of the light beams emitted from the dichroic prism 4 may be easily correspond to one another while reducing the light quantity loss caused by the bending stress.

The optical device 100 of the present embodiment may be an optical device employing the critical illumination, or may be an optical device employing the Koehler illumination.

In the optical device 100 of the present embodiment in which M (M is an integer equal to or greater than 3) light sources emitting light of different wavelengths are grouped into N (M>N≧2) groups includes N fibers that cause the light beams to directly enter the illumination optical system (i.e., guide the light beams to the optical system). Hereinafter, among the light sources grouped into N groups, a plurality of light sources of which emitted light beams are guided by the same fiber will be referred to as light source groups.

The optical device 100 is configured such that the number of fibers by which light beams are made to enter directly the illumination optical system is smaller than the number of the light sources and configured using fibers having different cutoff wavelengths. Among the fibers by which light beams are made to enter directly the illumination optical system, at least one fiber guides incident light beams from two or more light sources and another fiber guides incident light beams of wavelengths other than those of the light beams entering the above-mentioned at least one fiber. With this configuration, variation in light quantity loss may be reduced among different wavelengths as compared with a case in which all the light beams of a plurality of different wavelengths are guided by a single fiber. In a case in which a polarization maintaining fiber that may guide light beams while keeping a polarization plane is used, it is further possible to improve maintenance characteristics of the polarization plane.

It is also possible to secure life of the light sources and stability of output as compared with a case in which variation in light quantity loss is controlled by excessively increasing the output of the light source in which the light quantity loss is likely to become large. Since the light beams are not guided by the same number of fibers as that of the light sources, the number of optical paths emitted from the fibers in the illumination optical system may become smaller and, accordingly, the size of the optical device may be reduced.

### Second Embodiment

An optical device of the present embodiment is, as in the first embodiment, a microscope for which there is a demand that linearly polarized light polarized in a predetermined direction is to be illuminated.

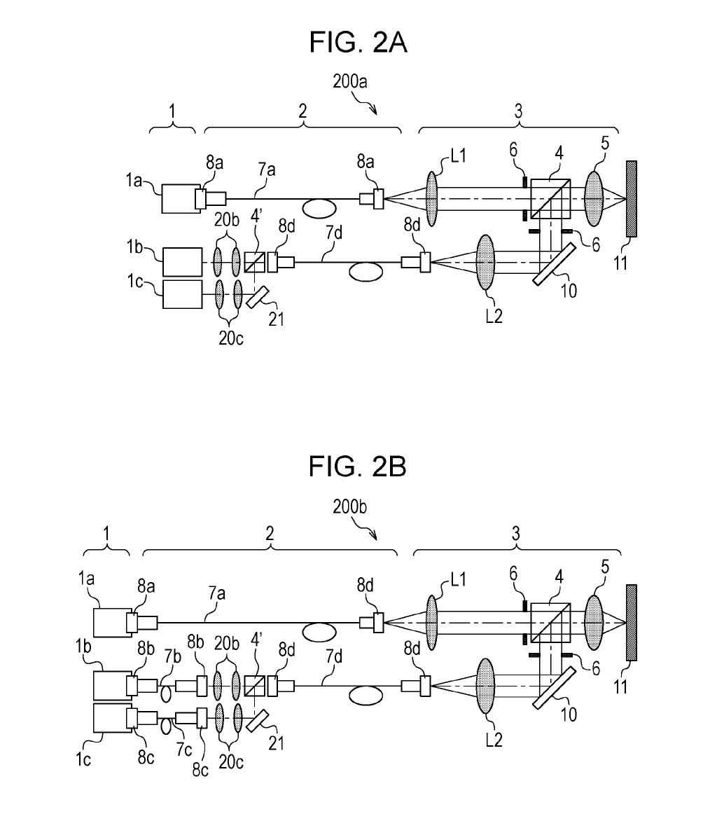

FIG. 2A is a diagram illustrating a configuration of an optical device 200a related to a second embodiment and FIG. 2B is a diagram illustrating a configuration of an optical device 200b related to the second embodiment. The second embodiment differs from the first embodiment in that no coupler 9 is used as a unit to compose light beams from the light source 1b and the light source 1c.

In FIG. 2A, light beams emitted from the same light source group (i.e., light sources 1b and 1c) are composed using lens systems 20b and 20c, a mirror 21 and a dichroic prism 4′ instead of the fibers 7b and 7c, the connector 8b and 8c and the coupler 9 in the first embodiment. A light beam emitted from the light source 1b is guided to the dichroic prism 4′ by the lens system 20b. A light beam emitted from the light source 1c is guided by the lens system 20c, changed its optical path at a mirror 21, and made to enter the dichroic prism 4′.

The dichroic prism 4′ composes the light beams emitted from the light sources 1b and 1c. Since no coupler 9 is used, there is an advantage that light quantity loss caused during the composition of light beams in the same light source group may be reduced.

FIG. 2B differs from the embodiment of FIG. 2A in that the fibers 7b and 7c and the connector 8b and 8c in the first embodiment are used as they are. The light beam emitted from the light source 1b is guided to the dichroic prism 4′ by the lens system 20b without using the coupler 9. On the other hand, the light beam emitted from the light source 1c is guided by the lens system 20c, changed its optical path at the mirror 21, and made to enter the dichroic prism 4′.

There is an advantage of reducing variation in light quantity loss by, as in the optical device 200a, composing the light beams in the same light source group using the dichroic prism 4′ instead of using a coupler. It is possible to increase a degree of freedom in arrangement of the light sources 1b and 1c by adjusting the length of the fibers 7b and 7c. It is also possible to prevent heat generated by the light sources 1b and 1c from affecting other peripheral devices. The light sources 1b and 1c and the fibers 7b and 7c are replaced by disconnecting the connectors 8b and 8c. Therefore, there is an effect that readjustment of the optical axes in the light guide unit 2 and the illumination optical system 3 is unnecessary.

### Third Embodiment

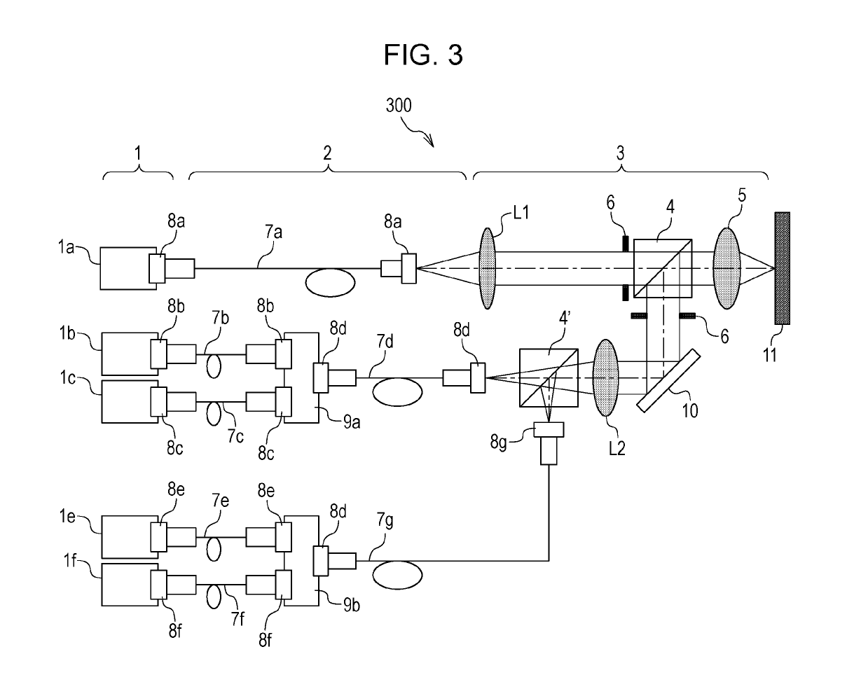

An optical device of the present embodiment is, as in the first and the second embodiments, a microscope capable of emitting a linearly polarized light polarized in a predetermined direction. FIG. 3 is a diagram illustrating a configuration of an optical device 300 according to a third embodiment. The third embodiment differs from the first embodiment in that the number of light sources 1 is five and that light beams are composed in a different way.

Since a configuration of a light guide unit 2 of light beams emitted from a light source 1a (a wavelength λ1), 1b (a wavelength λ2) and 1c (a wavelength λ3) is the same as that of the first embodiment, description thereof will be omitted. A wavelength of a light source 1e is set to λ4 and a wavelength of a light source 1f is set to λ5 (λl<λ2<λ3<λ4<λ5).

The light guide unit 2 is further provided with a fiber 7e which guides a light beam emitted from a light source 1e, and connectors 8e provided at both ends of the fiber 7e, and a fiber 7f which guides a light beam emitted from a light source 1f, and connectors 8f provided at both ends of the fiber 7f. The light guide unit 2 is further provided with a coupler 9b for composing the light beams guided by the fibers 7e and 7f and emitting the composed light beams to a fiber 7g, and connectors 8g provided at both ends of the fiber 7g. The fibers 7a to 7g are single-mode fibers for keeping a polarization direction of the light source 1 as much as possible.

In order to guide light beams of all the wavelengths in the single mode, it is desirable that a cutoff wavelength of each of the fibers 7a to 7g has a wavelength band of a length shorter than the shortest wavelength that enters each fiber. That is, it is desirable to select a fiber of which cutoff wavelength is shorter than λ1 as the fiber 7a, select a fiber of which cutoff wavelength is shorter than λ2 as the fiber 7d, and select a fiber of which cutoff wavelength is shorter than λ4 as the fiber 7g. Therefore, the fibers 7a, 7d and 7g are different in cutoff wavelength.

In the present embodiment, instead of respectively collimating the light beams emitted from the fibers 7a, 7d and 7g by the collimator lenses and then composing by a dichroic prism 4, the light beams emitted from the fibers 7d and 7g are once composed by a dichroic prism 4′. The light beams composed by the dichroic prism 4′ are made to enter the collimator lens L2. In this manner, the number of optical paths P of the light beams emitted from the fibers 7a to 7g to the illumination optical system 3 on which the collimator lenses are disposed is set to be smaller than the number of fibers N by which light beams are made to enter directly the illumination optical system.

In a case in which the wavelengths λ2, λ3, λ4 and λ5 are within a predetermined wavelength bandwidth and chromatic aberration caused when light beams are made to pass through the same collimator lens L2 is within a tolerance range on a target surface 11, it is desirable to apply the present embodiment. By reducing the number of the lenses disposed in the optical device 300 as small as possible, it is possible to avoid an increase in size and complication of the optical device 300 due to chromatic aberration correction. Further, as in the first and the second embodiments, there is an effect that variation in light quantity loss is reduced while reducing the size of the optical device 300 by setting the number N of the fibers 7a, 7d and 7g (N≧2) to be smaller than the number of light sources M.

The optical devices 100, 200a, 200b and 300 illustrated in the first to the third embodiments described above may be applied not only to the optical device of the microscope but also an optical pickup 400 and a position detector device 500 described later.

### Fourth Embodiment

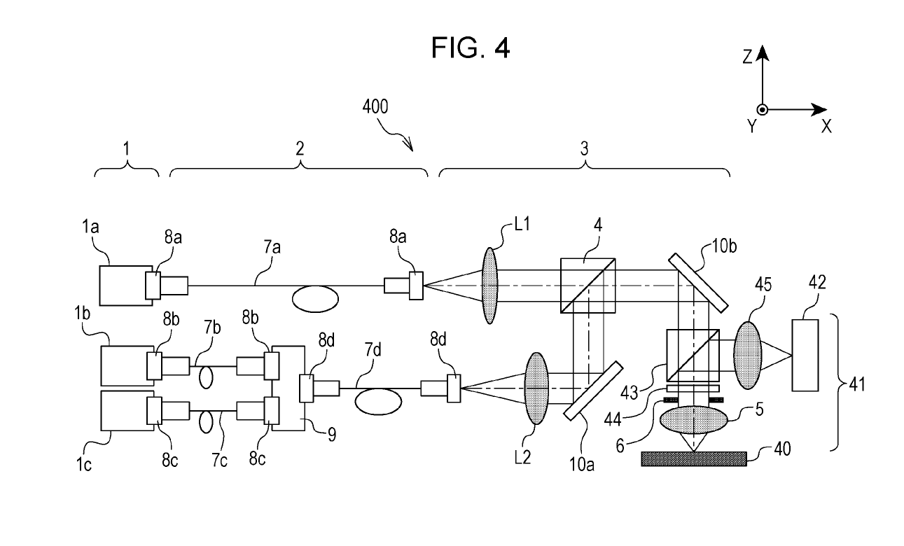

FIG. 4 illustrates a configuration of an optical pickup 400 according to a fourth embodiment. The optical pickup 400 is an optical pickup which may irradiate an optical disc 40, such as a CD and a DVD, as a target surface with light to read information in the optical disc 40. The optical pickup 400 irradiates the optical disc 40 with light emitted from a light source 1 via a light guide unit 2 and an illumination optical system 3. The light reflected on the optical disc 40 is detected by a detector 42 via a detection optical system 41. The information recorded on the optical disc 40 is read using an output signal in the detector 42.

Since a configuration until the light beams emitted from the light sources 1a, 1b and 1c are composed in the dichroic prism 4 in the light source 1, the light guide unit 2 and the illumination optical system 3 is the same as that of the first embodiment, description thereof will be omitted. The optical pickup 400 uses a polarized beam splitter 43 (hereafter, referred to as a beam splitter 43) described below. Therefore, it is desirable that the light emitted from the light source 1 is linearly polarized light and that the fibers 7a to 7d are single-mode fibers. In this configuration, by guiding the light while keeping a polarization plane, occurrence of large light quantity loss caused by light that is not able to pass through the beam splitter 43 may be prevented.

Semiconductor laser is used as the light source 1 and linearly polarized light is obtained. In order to prepare the light source 1 in accordance with the kind of the optical disc 40 which is the target surface 11, for example, a wavelength λ1 of the light source 1a is set to 405 nm, a wavelength λ2 of the light source 1b is set to 650 nm and a wavelength λ3 of the light source 1c is set to 780 nm. As a light source having a wavelength of about 400 nm, GaN-based blue-violet semiconductor laser, SHG-based blue-violet laser and the like are used.

The illumination optical system 3 is further provided with a mirror 10b which reflects the light beams composed by the dichroic prism 4, a beam splitter 43, a λ/4 plate 44, aperture diaphragms 6 and an objective lens 5. The beam splitter 43 transmits p-polarized light which vibrates in a plane parallel to an incident plane of the light with respect to the beam splitter 43 (i.e., a plane parallel to a YZ plane) and reflects s-polarized light which vibrates in a direction perpendicular to an incident plane of the light (i.e., a plane parallel to an XZ plane) to a direction vertical to an incident direction.

The p-polarized light passes through the λ/4 plate 44 and is converted into circularly polarized light, and the converted circularly polarized light forms an image on the optical disc 40 by the objective lens 5 via an aperture diaphragm 6. Here, numerical apertures of the objective lens 5 is set to be equal to or greater than 0.6 which is a general value in the optical pickup 400.

The detection optical system 41 is provided with the objective lens 5, the aperture diaphragm 6, the λ/4 plate 44, the beam splitter 43 and an image forming lens 45. That is, the objective lens 5, the aperture diaphragm 6, the λ/4 plate 44 and the beam splitter 43 belong to both the illumination optical system 3 and the detection optical system 41.

The light from the optical disc 40 irradiated by the objective lens 5 (including either of regular reflection light, reflected diffraction light of reflected scattered light, or combination thereof) becomes circularly polarized light of which rotational direction is opposite to that of illuminated circularly polarized light. Therefore, although the circularly polarized light which has again passed through the objective lens 5 and the aperture diaphragm 6 returns to be linearly polarized light by the λ/4 plate 44, the reflected light turns into s-polarized linearly polarized light and, therefore, is reflected by the beam splitter 43 in a direction perpendicular to the incident direction. Then, the image forming lens 45 forms an image in the detector 42 and the detector 42 reads information by detecting an optical signal.

In a case in which the beam splitter 43 is used as in the present embodiment, polarization maintaining fibers are used as the fibers 7a to 7d and directions of emission ports are adjusted such that polarized light beams emitted from the emission ports of the polarization maintaining fibers are polarized in predetermined directions. In this manner, it is desirable to align polarization directions of composed light beams by setting angular deviation in the polarization direction of the polarized light beams after composition in the dichroic prism 4 to be smaller than angular deviation in the polarization direction of the polarized light beams entering the fibers 7a and 7d.

A degree of light quantity loss after passing through the beam splitter 43 is reduced and variation in light quantity loss is reduced. The optical pickup 400 is capable of reducing a decrease in contrast of illumination light and reducing a decrease in reading accuracy of the optical signal.

The optical pickup is often placed in a limited installation space. Therefore, the configuration in which the number of fibers N (N≧2) by which light beams are made to enter directly the illumination optical system is smaller than the number of light sources M is advantageous in that the size of the optical pickup is reducible while reducing variation in light quantity loss. Since variation in light quantity loss is reducible, it is possible to form circularly polarized light with smaller deviation in light quantity depending on the wavelength and, therefore, it is possible to reduce a reading error of information at each position on the optical disc.

### Fifth Embodiment

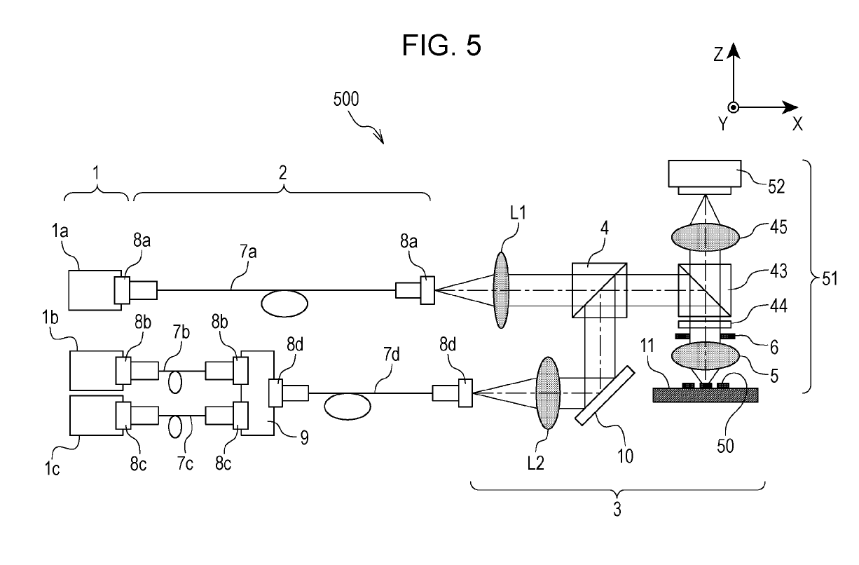

FIG. 5 illustrates a configuration of a position detector device 500 according to a fifth embodiment. The position detector device 500 is an optical device which irradiates a target surface 11, such as a wafer (i.e., a substrate), with light emitted from a light source 1, and detects a position of a mark 50 formed on the target surface 11. The position detector device 500 is provided with the light source 1, a light guide unit 2, an illumination optical system 3 and a detection optical system 51 for detecting position.

Since a configuration until the light beams emitted from the light sources 1a, 1b and 1c are composed in the dichroic prism 4 in the light source 1, the light guide unit 2 and the illumination optical system 3 is the same as that of the fourth embodiment, description thereof will be omitted. The position detector device 500 also uses a beam splitter 43. Therefore, it is desirable that the light emitted from the light source 1 is linearly polarized light and that the fibers 7a to 7d are single-mode fibers. In this configuration, by guiding the light while keeping a polarization plane, occurrence of large light quantity loss from occurring at the beam splitter 43 may be prevented.

As light sources 1a to 1c, light sources emitting linearly polarized light beams of different wavelengths are used. The wavelengths of the light sources 1a to 1c of the present embodiment are λ1=450 nm, λ2=635 nm and λ3=780 nm, respectively. It is desirable that the wavelengths of the light sources 1a to 1c do not distribute in a narrow band. In this manner, it is possible to reduce that measurement accuracy in marks 50 formed at different positions is varied due to an influence of wavelength dependency of reflectance at each position on the target surface 11.

Guiding light beams by the fiber 7d in combination of light sources with large wavelength differences, such as λ2=450 nm and λ3=780 nm, should be avoided because variation in light quantity loss during guidance of the light beams is likely to become larger.

Light beams composed by the dichroic prism 4 enter the beam splitter 43. The beam splitter 43 transmits p-polarized light parallel to a Y-axis and reflects s-polarized light parallel to an X-axis toward the target surface 11. The s-polarized light reflected by the beam splitter 43 illuminates the target surface 11 via a λ/4 plate 44, an aperture diaphragm 6 and an objective lens 5.

The detection optical system 51 is provided with the objective lens 5, the aperture diaphragm 6, the λ/4plate 44, the beam splitter 43, an image forming lens 45 and a detector 52. As the detector 52, an imaging element, such as CMOS and CCD, is used. That is, the objective lens 5, the aperture diaphragm 6, the λ/4 plate 44 and the beam splitter 43 belong to both the illumination optical system 3 and the detection optical system 51.

The light from the mark 50 (including either of regular reflection light, reflected diffraction light or reflected scattered light, or combination thereof) passes through the objective lens 5, the aperture diaphragm 6 and the λ/4 plate 44 again and enters the beam splitter 43. The s-polarized light reflected by the beam splitter 43 is illuminated on the mark 50 as circularly polarized light by the same effect as that of the fourth embodiment and returns to be linearly polarized light by passing through the λ/4 plate 44 again.

A rotational direction of the s-polarized light-based circularly polarized light enters the beam splitter 43 again. Then the light forms an image of the mark 50 in the detector 52 by the lens 45. The detector 52 obtains a position of the mark 50 on the target surface 11 based on the image of the mark 50.

The configuration in which the number of fibers N (N≧2) by which light beams are made to enter directly the illumination optical system is smaller than the number of light sources M is advantageous in that the size of the optical device is reducible while reducing variation in light quantity loss of light beams of a plurality of wavelengths passing through the same fiber and reducing an influence of occurrence of aberration.

### Sixth Embodiment

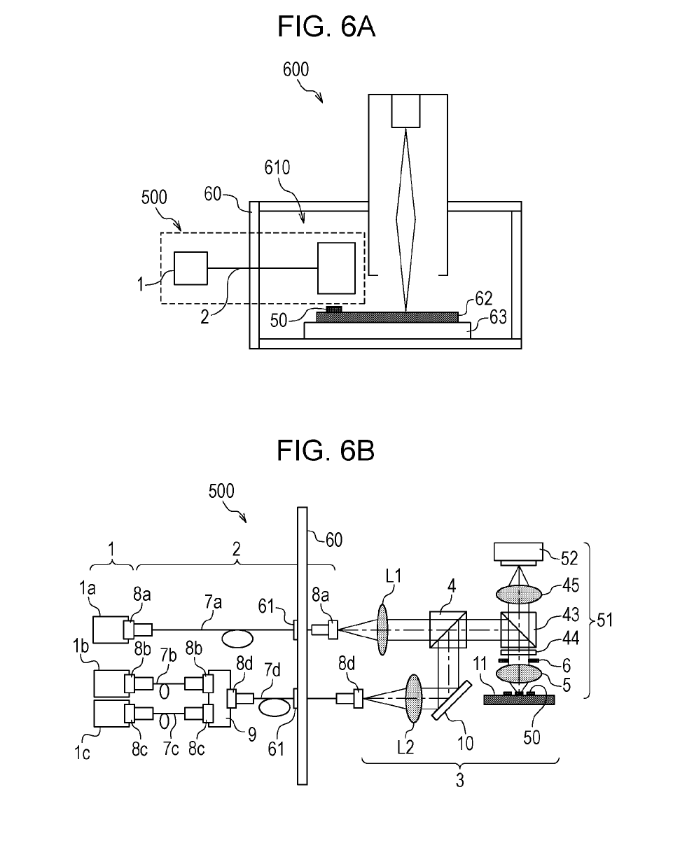

FIG. 6A is a diagram illustrating a lithography apparatus 600. The position detector device 500 of the fifth embodiment may be applied to the lithography apparatus 600, such as an exposure device exposing beams like light beams and electron beams, and an imprint device. The position detector device 500 is used to detect a position of a mark 50 formed on a wafer 62 which is a target surface.

In the case of the present embodiment, in order not to expose unillustrated resist applied to the wafer 62, it is desirable to use light emitted from the light source 1 of a wavelength equal to or greater than 450 nm. It is more desirable to use light of a wavelength band of 450 nm to 800 nm.

In the lithography apparatus 600 illustrated in

FIG. 6A, the wafer 62 which is a target surface of the beam of the lithography apparatus 600 exists in an exposure space 610 (hereafter, referred to as a chamber 610) of a vacuum atmosphere (i.e., a depressurized condition) or a gas atmosphere. In such a case, there is a possibility that heat generated in the light source 1 of the position detector device 500 adversely affects measurement accuracy of other measurement devices in the chamber 610.

Then, it is desirable to dispose the light source 1 outside the chamber 610 via a partition 60 of the chamber 610. Here, the fibers 7a and 7d are disposed to penetrate the partition 60 in order to guide light into the chamber 610.

FIG. 6B is an enlarged view of a peripheral portion of the position detector device 500 in FIG. 6A. If light beams of a plurality of wavelengths emitted from the light sources 1 are guided by a single fiber, since the fiber is bent due to vibration or stress of a partition 60, light quantity loss is varied for each wavelength of light passing through the fiber, or chromatic aberration is caused. On the other hand, in a configuration in which the same number of fibers as that of the light sources are prepared to guide the light beams via the partition 60, the number of flanges 61 for fixing the fibers may be increased and a space occupied by the illumination optical system 3 in a chamber 610 may be increased.

Therefore, also in the present embodiment, the light beams from M (M≧3) light sources which emit light beams of different wavelengths are grouped into light source groups to be guided by N fibers and the light beams from the light source 1 are guided via the partition 60. It is desirable that the light beams guided by each fiber are close in wavelength as much as possible. This provides an effect that variation in light quantity loss among wavelengths caused until the light beams are composed by the dichroic prism 4 may be reduced as compared with a case in which the light beams are guided only by a single fiber.

Since the position detector device 500 is compact in size as compared with a position detector device in which white LED and the like emitting light of a wide wavelength is used as the light source 1, it is possible to dispose the illumination optical system 3 of the position detector device 500 near a beam that illuminates the target surface 11. Therefore, it is possible to reduce a moving amount of a stage 63 illustrated in FIG. 6A holding and driving the target surface 11 when the position of the mark 50 is detected.

The position detector device 500 may also be used as a device for measuring a height of the wafer 62 or as an optical device for an inspection apparatus that inspects superposition accuracy of superimposed patterns formed on a wafer.

### Other Embodiments

The present invention is applicable to cases in which the number of the light sources 1 emitting light beams of different wavelengths is three or more and, therefore, the number of the light sources 1 is not necessarily limited to three or five as in the described embodiments. The light sources may be contained in a casing in unit of light source group.

The light source 1 may also be LED of each color, a halogen lamp, and the like in addition to the laser light source. In a case in which the light emitted from the light source is unpolarized light, the unpolarized light is made to enter a polarization element (not illustrated), such as a polarization plate, and linearly polarized light is taken out for use. In a case in which a halogen lamp is used, if some halogen lamps are used in combination, light beams are emitted in different wavelengths. A halogen lamp may be used in combination with other types of light sources.

### Manufacturing Method of Article

A manufacturing method of an article (e.g., a semiconductor integrated circuit element, a liquid crystal display element, a CD-RW and a photomask) of the present invention includes a process of forming a pattern on a substrate, such as a Si wafer or glass, using a lithography apparatus, such as an exposure device exposing beams, like light beams and electron beams, and an imprint device, which includes the above-described optical device. The manufacturing method further includes a process of performing at least one of etching and ion implantation treatment to the substrate on which the pattern is formed. Further, the method may include other known processes (e.g., development, oxidization, film formation, vapor deposition, doping, smoothing, resist removing, dicing, bonding and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-272042, filed Dec. 27, 2013 which is hereby incorporated by reference herein in its entirety.

What is claimed is:

1. An optical device provided with an optical system illuminating light on a target surface, the optical device comprising:
three light sources configured to emit light beams of different wavelengths;
a first fiber configured to guide, to the optical system, two light beams among the three light beams from the three light sources; and
a second fiber configured to guide, to the optical system, the light beam of a wavelength other than the two light beams,
wherein a cutoff wavelength of the first fiber differs from a cutoff wavelength of the second fiber.

2. The optical device according to claim 1, wherein the wavelength band of the cutoff wavelength of the first fiber consists of a wavelength shorter than the shortest wavelengths of the two light beams.

3. The optical device according to claim 1, wherein the first fiber guides two light beams of wavelengths close to each other among the three light beams.

4. The optical device according to claim 1, wherein the light beams entering the first and the second fibers are polarized light beams, and angular deviation of a polarization plane among the polarized light beams illuminating the target surface is smaller than angular deviation of a polarization plane among the polarized light beams entering the first and the second fibers.

5. The optical device according to claim 1, wherein the first fiber and the second fiber are polarization maintaining fibers, and the optical system includes a polarized beam splitter.

6. The optical device according to claim 1, wherein all of wavelengths of the three light sources are equal to or greater than 450 nm.

7. An optical device provided with an optical system which illuminates a target surface with polarized light beams, comprising:
a first polarization maintaining fiber configured to guide, to the optical system, two polarized light beams having wavelengths close to each other among three polarized light beams of different wavelengths; and
a second polarization maintaining fiber configured to guide, to the optical system, a polarized light beam of which wavelength is longer than those of either of the two polarized light beams,
wherein a cutoff wavelength of the second polarization maintaining fiber is longer than a cutoff wavelength of the first polarization maintaining fiber.

8. An optical device provided with an optical system which illuminates a target surface with polarized light beams, comprising:
a first polarization maintaining fiber configured to guide, to the optical system, two polarized light beams having wavelengths close to each other among three polarized light beams of different wavelengths; and
a second polarization maintaining fiber configured to guide, to the optical system, a polarized light beam of which wavelength is shorter than those of either of the two polarized light beams,
wherein a cutoff wavelength of the second polarization maintaining fiber is shorter than a cutoff wavelength of the first polarization maintaining fiber.

9. A lithography apparatus, comprising a position detector device configured to detect a position of a mark formed on a substrate, wherein the position detector device is the optical device according to claim 1.

10. The lithography apparatus according to claim 8, further comprising a chamber configured to keep an exposure space in a depressurized condition, wherein the first and the second fibers of the position detector device penetrate a partition of the chamber.

11. A lithography apparatus, comprising a position detector device configured to detect a position of a mark formed on a substrate, wherein the position detector device is the optical device according to claim 7.

12. The lithography apparatus according to claim 10, further comprising a chamber configured to keep an exposure space in a depressurized condition, wherein the first and the second fibers of the position detector device penetrate a partition of the chamber.

13. A manufacturing method of an article, comprising:
a process of exposing a substrate using a lithography apparatus; and a process of performing at least one of etching and ion implantation treatment to the substrate,
wherein the lithography apparatus is
an optical device provided with an optical system illuminating light on a target surface, including
three light sources configured to emit light beams of different wavelengths,
a first fiber configured to guide, to the optical system, two light beams among the three light beams from the three light sources, and
a second fiber configured to guide, to the optical system, the light beam of a wavelength other than the two light beams,
wherein a cutoff wavelength of the first fiber differs from a cutoff wavelength of the second fiber.
